(19) United States
(12) Patent Application Publication
(10) Pub. No.: US 2020/0133138 A1
(43) Pub. Date: Apr. 30, 2020

(54) METHOD AND DEVICE FOR IMPROVING EXPOSURE ACCURACY

(71) Applicant: WUHAN CHINA STAR OPTOELECTRONICS TECHNOLOGY CO., LTD, Wuhan (CN)

(72) Inventor: Yuchang GUI, Wuhan, Hubei (CN)

(21) Appl. No.: 16/484,119

(22) PCT Filed: Apr. 26, 2019
(86) PCT No.: PCT/CN2019/084490

§ 371 Date: Aug. 7, 2019

(30) Foreign Application Priority Data
Sep. 28, 2018 (CN) 201811141189.0

(51) Int. Cl. G03F 7/20

(52) U.S. Cl. CPC G03F 7/70433

(57) ABSTRACT

A method and a device for improving exposure accuracy are provided. After an exposure area is defined on a substrate, a plurality of exposure points from the exposure area are acquired to obtain a set of the exposure points, and then a plurality of exposure offset values corresponding to the exposure points in the set of the exposure points are detected respectively, to obtain a set of the exposure offset values. Then, based on the set of the exposure offset values, the exposure points corresponding to each of the exposure offset values are corrected.

### FIELD OF DISCLOSURE

The present disclosure relates to the field of display technologies, and in particular, to a method and a device for improving exposure accuracy.

### BACKGROUND

An exposure machine is required in a photolithography process of a liquid crystal display panel process. An exposure process is performed by the exposure machine on a glass substrate coated with a photoresist film and a mask. In this step, an accuracy of a position of the exposure determines an alignment and fabrication accuracy of the glass substrate in subsequent processes. If the exposure position is deviated, the position of patterns in a next process cannot be matched, which may cause transistors in the substrate to be unable to conduct, or may cause light leakage in red, green, and blue pixels in a color film substrate. Therefore, it is possible to offset the alignment between the substrate and the color film substrate, thereby affecting a product yield during cell-assembling process.

### SUMMARY OF DISCLOSURE

The technical problem mainly solved by the present disclosure is how to improve the exposure accuracy and thereby improve the product yield.

In one aspect, one embodiment of the present disclosure provides a method of improving exposure accuracy, including:

defining an exposure area on a substrate;

acquiring a plurality of exposure points from the exposure area, to obtain a set of the exposure points;

detecting a plurality of exposure offset values corresponding to the exposure points in the set of the exposure points, respectively, to obtain a set of the exposure offset values; and

correcting the exposure points corresponding to the exposure offset values, respectively, based on the set of the exposure offset values;

wherein the step of acquiring the plurality of exposure points from the exposure area, to obtain the set of the exposure points, includes:

acquiring a plurality of exposure patterns from the exposure area;

acquiring corresponding exposure points of each of the exposure patterns, to obtain a plurality of subsets of the exposure points corresponding to each of the exposure patterns; and

determining the set of the exposure points based on the plurality of subsets of the exposure points;

wherein the step of detecting the plurality of exposure offset values corresponding to the exposure points in the set of the exposure points, respectively, to obtain the set of the exposure offset values, includes:

acquiring exposure values corresponding to the exposure points in the set of the exposure points, respectively;

calculating differences between the exposure values and preset reference values corresponding to the exposure points, respectively, to obtain the plurality of exposure offset values; and

constructing the set of the exposure offset values according to the plurality of exposure offset values.

In second aspect, one embodiment of the present disclosure provides a method of improving exposure accuracy, including:

defining an exposure area on a substrate;

acquiring a plurality of exposure points from the exposure area, to obtain a set of the exposure points;

detecting a plurality of exposure offset values corresponding to the exposure points in the set of the exposure points, respectively, to obtain a set of the exposure offset values; and

correcting the exposure points corresponding to the exposure offset values, respectively, based on the set of the exposure offset values.

In third aspect, one embodiment of the present disclosure provides a device of improving exposure accuracy, including:

an exposure unit configured to define an exposure area on a substrate;

an acquiring unit configured to acquire a plurality of exposure points from the exposure area, to obtain a set of the exposure points;

a detection unit configured to detect a plurality of exposure offset values corresponding to the exposure points in the set of the exposure points, respectively, to obtain a set of the exposure offset values; and

a correction unit configured to correct the exposure points corresponding to the exposure offset values, respectively.

In the device of improving exposure accuracy of the present disclosure, the acquiring unit is also configured to:

acquire a plurality of exposure patterns from the exposure area;

acquire corresponding exposure points of each of the exposure patterns, to obtain a plurality of subsets of the exposure points corresponding to each of the exposure patterns; and

determine the set of the exposure points based on the plurality of subsets of the exposure points.

In the device of improving exposure accuracy of the present disclosure, the detection unit is also configured to:

acquire exposure values corresponding to the exposure points in the set of the exposure points, respectively;

calculate differences between the exposure values and preset reference values corresponding to the exposure points, respectively, to obtain the plurality of exposure offset values; and;

construct the set of the exposure offset values according to the plurality of exposure offset values.

Advantages of the present disclosure are as follows: the exposure points are corrected based on the offset values of the exposure points, which can effectively improve the exposure accuracy and thus improve the product yield.

### BRIEF DESCRIPTION OF DRAWINGS

In order to more clearly understand the technical scheme of the exemplary embodiments of the present disclosure, accompanying figures that are needed for the description of the exemplary embodiments are briefly introduced below. Understandably, the following figures only constitute a few exemplary embodiments of the present disclosure. Based on these accompanying figures, one of ordinary skills in the art can obtain other figures without making any creative effort.

FIG. 1 is a flowchart of a method of improving exposure accuracy according to an embodiment of the present disclosure.

FIG. 2 is a schematic diagram of exposure patterns according to an embodiment of the present disclosure.

FIG. 3 is a schematic diagram of a feedback coordinate system in a method of improving exposure accuracy according to an embodiment of the present disclosure.

FIG. 4 is an enlarged view of the schematic diagram of the exposure patterns shown in FIG. 2.

FIG. 5 is a schematic diagram of a device of improving exposure accuracy according to an embodiment of the present disclosure.

### DETAILED DESCRIPTION

The embodiments of the present disclosure will be described in detail below with reference to the accompanying drawings in which same or similar reference numerals indicate the same or similar elements, or elements with same or similar function. The embodiments described below with reference to the accompanying drawings are exemplary and are merely used to explain the present disclosure, but should not be construed as limiting the present disclosure.

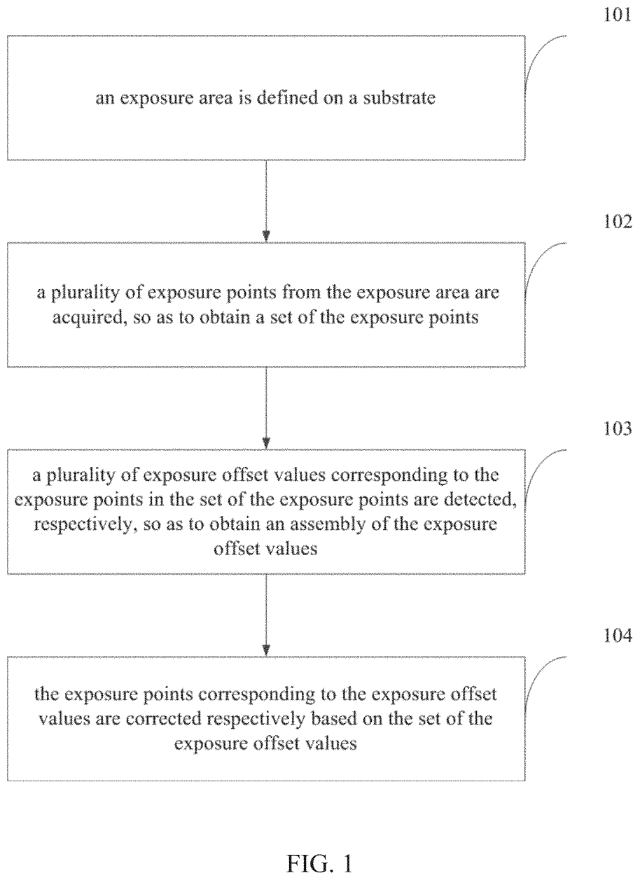

Please refer to FIG. 1, which is a flowchart of a method of improving exposure accuracy according to an embodiment of the present disclosure.

The present disclosure provides a method of improving exposure accuracy, including:

101, an exposure area is defined on a substrate.

For example, the substrate can be exposed by an exposure machine to define the exposure area on the substrate. The substance can be a glass substrate.

102, a plurality of exposure points from the exposure area are acquired, so as to obtain a set of the exposure points.

Specifically, after the exposure area is defined on the substrate, all exposure points on the exposure area can be acquired. For example, the set of the exposure points can be obtained by acquiring exposure patterns from the exposure area and then acquiring the exposure points of each of the exposure patterns.

That is, in some embodiments, the step of acquiring the exposure points from the exposure area to obtain the set of the exposure points may include:

acquiring a plurality of exposure patterns from the exposure area;

acquiring corresponding exposure points of each of the exposure patterns, to obtain a plurality of subsets of the exposure points corresponding to each of the exposure patterns;

determining the set of the exposure points based on the plurality of subsets of the exposure points.

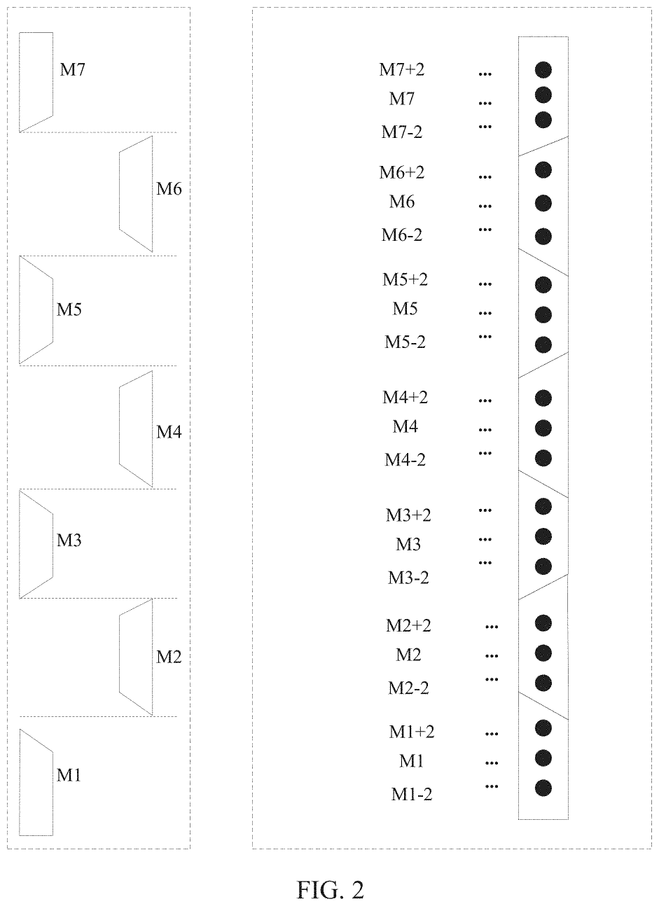

For example, during the exposure process, the substrate may first be exposed using a lens having a plurality of predetermined patterns. The plurality of predetermined exposure patterns may be M1, M2, M3, M4, M5, M6, and M7, and the formed exposure patterns may be M1+2, M1, M1−2, and the like. As shown in FIG. 2, in some embodiments, the exposure points in the exposure patterns may be arranged in a matrix, but the shape of the exposure patterns is not limited thereto, and may have other shapes, which are merely exemplified in the embodiment of the present disclosure.

However, in the implementation process, the acquired image definitions of the exposure patterns may not be clear. Therefore, after acquiring the plurality of exposure patterns from the exposure area, the image definitions of the exposure patterns can also be detected.

That is, in some embodiments, between the step of acquiring the plurality of exposure patterns from the exposure area and the step of acquiring corresponding exposure points of each of the exposure patterns, the method further includes:

detecting a plurality of image definitions of the plurality of exposure patterns;

acquiring corresponding exposure patterns whose the image definitions satisfy a preset condition, to obtain a plurality of exposure patterns to be extracted.

The step of acquiring corresponding exposure points of each of the exposure patterns, to obtain the plurality of subsets of the exposure points corresponding to each of the exposure patterns, includes: acquiring the exposure points of each of the exposure patterns to be extracted, to obtain the subsets of the exposure points corresponding to each of the exposure patterns to be extracted.

For example, the image definitions for each exposure pattern can be detected, and then determine whether the image definitions of each exposure patterns meet the preset condition. The preset condition can be a predetermined image definition.

That is, in some embodiments, the step of acquiring corresponding exposure patterns whose the image definitions satisfy a preset condition, to obtain a plurality of exposure patterns to be extracted, includes:

determining corresponding exposure patterns to be currently processed, to obtain a current processing object;

determining whether the image definition of the current processing object satisfies the preset condition or not;

if the image definition of the current processing object satisfies the preset condition, determining that the current processing object is one of the exposure patterns to be extracted;

returning to the step of determining corresponding exposure patterns to be currently processed, until all of the exposure patterns have been determined.

For example, the image definition of the current processing object.

103, a plurality of exposure offset values corresponding to the exposure points in the set of the exposure points are detected, respectively, so as to obtain a set of the exposure offset values.

For example, the exposure values corresponding to the exposure points in the set of the exposure points can be detected respectively. Then, the difference between the exposure value and preset reference values corresponding to the exposure points are calculated respectively, thereby obtaining the exposure offset values corresponding to the exposure points. Then, the set of the exposure offset values is constructed based on these exposure offset values.

That is, in some embodiments, the step of detecting the plurality of exposure offset values corresponding to the exposure points in the set of the exposure points, respectively, to obtain the set of the exposure offset values, includes:

acquiring exposure values corresponding to the exposure points in the set of the exposure points, respectively;

calculating differences between the exposure values and preset reference values corresponding to the exposure points, respectively, to obtain the plurality of exposure offset values;

constructing the set of the exposure offset values according to the plurality of exposure offset values.

104, the exposure points corresponding to the exposure offset values are corrected respectively based on the set of the exposure offset values.

For example, the offsets of the exposure points and a preset reference point can be determined according to the exposure offset values corresponding to the exposure points. Then, the substrate is re-exposed according to the offsets to obtain new exposure points, thereby correcting the exposure points, respectively.

In some embodiments, the step of correcting the exposure points corresponding to the exposure offset values, respectively, based on the set of the exposure offset values, includes:

constructing a feedback coordinate system of the set of the exposure points based on the set of the exposure offset values;

marking a plurality of coordinates of the exposure points in the feedback coordinate system, respectively, to obtain a plurality of feedback coordinates corresponding to the exposure points;

correcting the feedback coordinates corresponding to the exposure points, respectively, according to the exposure offset values corresponding to the exposure points.

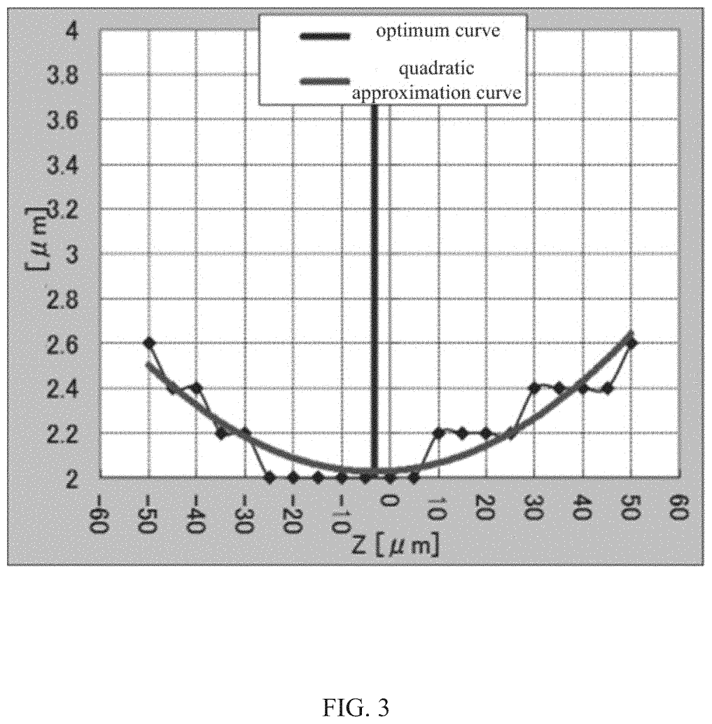

For example, as shown in FIG. 3, the feedback coordinate system of the set of the exposure points is constructed according to the set of the exposure offset values. Then, the exposure points are marked in the feedback coordinate system to acquire the feedback coordinates for the exposure points. Moreover, according to the exposure offset values corresponding to the exposure points, the offsets of the exposure points and the preset reference point are determined, and then the feedback coordinates of the exposure points are respectively corrected according to the offsets. There are many ways to correct the feedback coordinates of the exposure points. For example, the coordinates of the exposure points can be corrected by a translation method to achieve a purpose of correcting the exposure points.

That is, in some embodiments, the step of correcting the feedback coordinates corresponding to the exposure points, respectively, according to the exposure offset values corresponding to the exposure points, includes:

determining which ones of the exposure points require to be currently corrected, to obtain a current correction object;

translating the current correction object to a preset position of the feedback coordinate system;

returning to the step of determining which ones of the exposure points require to be currently corrected, until all of the exposure points have been corrected.

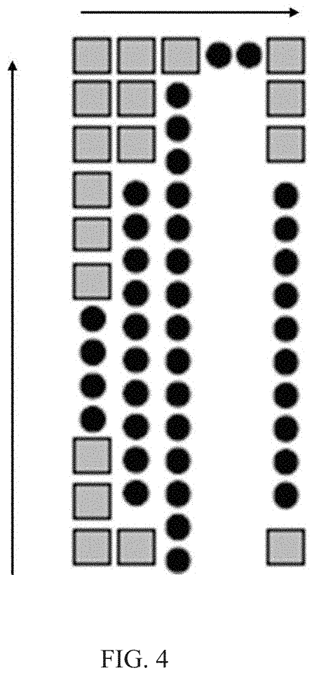

It should be noted that in the present embodiment, there are many methods for constructing the feedback coordinate system of the set of the exposure points. For example, the feedback coordinate system of the exposure points can be constructed directly from the positions of the exposure points, or the feedback coordinate system can be constructed according to the patterns corresponding to the exposure points. For example, the plurality of exposure patterns are obtained in step (11), and then a single exposure pattern is processed to obtain an enlarged view of the single exposure pattern. This enlarged view is as shown in FIG. 4. Then, according to the enlarged view of the single exposure pattern, a value corresponding to the enlarged view is searched in a preset look-up table. Then, the feedback coordinate system is constructed based on this value.

In the method of improving exposure accuracy provided by the embodiment of the present disclosure, after the exposure area is defined on the substrate, the exposure points from the exposure area are first acquired to obtain the set of the exposure points. Then, the exposure offset values corresponding to the exposure points in the set of the exposure points are respectively detected, to obtain the set of the exposure offset values. Then, based on the set of the exposure offset values, the exposure points corresponding to each of the exposure offset values are corrected. In the embodiment of the present disclosure, the exposure points are corrected based on the offset values of the exposure points, which can effectively improve the exposure accuracy, thereby improving the product yield.

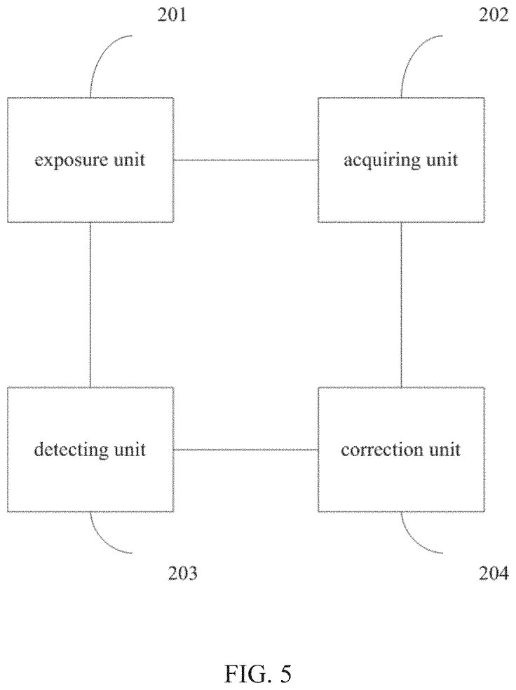

The present disclosure also provides a device of improving exposure accuracy, and hereinafter referred to as a device. Referring to FIG. 5, the device may include an exposure unit 201, an acquiring unit 202, a detecting unit 203, and a correction unit 204. The details can be as follows:

The exposure unit 201 is configured to define an exposure area on a substrate.

The acquiring unit 202 is configured to acquire a plurality of exposure points from the exposure area, to obtain a set of the exposure points.

The detection unit 203 is configured to detect a plurality of exposure offset values corresponding to the exposure points in the set of the exposure points, respectively, to obtain a set of the exposure offset values.

The correction unit 204 is configured to correct the exposure points corresponding to the exposure offset values, respectively.

In some embodiments, the acquiring unit 202 can be specifically used to:

acquire a plurality of exposure patterns from the exposure area;

acquire corresponding exposure points of each of the exposure patterns, to obtain a plurality of subsets of the exposure points corresponding to each of the exposure patterns;

determine the set of the exposure points based on the plurality of subsets of the exposure points.

In some embodiments, the detection unit 203 can be specifically used to:

acquire exposure values corresponding to the exposure points in the set of the exposure points, respectively;

calculate differences between the exposure values and preset reference values corresponding to the exposure points, respectively, to obtain the plurality of exposure offset values;

construct the set of the exposure offset values according to the plurality of exposure offset values.

In the device of improving exposure accuracy provided by the embodiment of the present disclosure, after the exposure area is defined on the substrate by the exposure unit 201, the acquiring unit 202 acquires the exposure points from the exposure area, to obtain the set of the exposure points. Then, the detection unit 203 detects the exposure offset values corresponding to the exposure points in the set of the exposure points, respectively, to obtain the set of the exposure offset values. Then, based on the set of the exposure offset values, the correction unit 204 corrects the exposure points corresponding to each of the exposure offset values. In the embodiments of the present disclosure, the exposure points are corrected based on the offset values of the exposure points, which can effectively improve the exposure accuracy, thereby improving the product yield.

In the above embodiments, the embodiments are depicted with different focus, and portions not depicted in a certain embodiment may be found in related depictions in other embodiments.

The method and device for improving exposure accuracy according to the present disclosure is described in detail hereinbefore. The principle and the embodiments of the present disclosure are illustrated herein by specific examples. The above description of examples is only intended to help the understanding of the method and the idea of the present disclosure. It should be noted that, for those skilled in the art, a few of modifications and improvements may be made to the present disclosure without departing from the principle of the present disclosure, and these modifications and improvements are also deemed to fall into the scope of the present disclosure defined by the claims.

What is claimed is:

1. A method of improving exposure accuracy, comprising:
defining an exposure area on a substrate;
acquiring a plurality of exposure points from the exposure area, to obtain a set of the exposure points;
detecting a plurality of exposure offset values corresponding to the exposure points in the set of the exposure points, respectively, to obtain a set of the exposure offset values; and
correcting the exposure points corresponding to the exposure offset values, respectively, based on the set of the exposure offset values;
wherein the step of acquiring the plurality of exposure points from the exposure area, to obtain the set of the exposure points, comprises:
acquiring a plurality of exposure patterns from the exposure area;
acquiring corresponding exposure points of each of the exposure patterns, to obtain a plurality of subsets of the exposure points corresponding to each of the exposure patterns; and
determining the set of the exposure points based on the plurality of subsets of the exposure points;
wherein the step of detecting the plurality of exposure offset values corresponding to the exposure points in the set of the exposure points, respectively, to obtain the set of the exposure offset values, comprises:
acquiring exposure values corresponding to the exposure points in the set of the exposure points, respectively;
calculating differences between the exposure values and preset reference values corresponding to the exposure points, respectively, to obtain the plurality of exposure offset values; and
constructing the set of the exposure offset values according to the plurality of exposure offset values.

2. The method as claimed in claim 1, wherein between the step of acquiring the plurality of exposure patterns from the exposure area and the step of acquiring corresponding exposure points of each of the exposure patterns, the method further comprises:
detecting a plurality of image definitions of the plurality of exposure patterns; and
acquiring corresponding exposure patterns whose the image definitions satisfy a preset condition, to obtain a plurality of exposure patterns to be extracted;
wherein the step of acquiring corresponding exposure points of each of the exposure patterns, to obtain the plurality of subsets of the exposure points corresponding to each of the exposure patterns, comprises: acquiring the exposure points of each of the exposure patterns to be extracted, to obtain the subsets of the exposure points corresponding to each of the exposure patterns to be extracted.

3. The method as claimed in claim 2, wherein the step of acquiring corresponding exposure patterns whose the image definitions satisfy the preset condition, to obtain the plurality of exposure patterns to be extracted, comprises:
determining corresponding exposure patterns to be currently processed, to obtain a current processing object;
determining whether the image definition of the current processing object satisfies the preset condition or not;
if the image definition of the current processing object satisfies the preset condition, determining that the current processing object is one of the exposure patterns to be extracted; and
returning to the step of determining corresponding exposure patterns to be currently processed, until all of the exposure patterns have been determined.

4. The method as claimed in claim 1, wherein the step of correcting the exposure points corresponding to the exposure offset values, respectively, based on the set of the exposure offset values, comprises:
constructing a feedback coordinate system of the set of the exposure points based on the set of the exposure offset values;
marking a plurality of coordinates of the exposure points in the feedback coordinate system, respectively, to obtain a plurality of feedback coordinates corresponding to the exposure points; and
correcting the feedback coordinates corresponding to the exposure points, respectively, according to the exposure offset values corresponding to the exposure points.

5. The method as claimed in claim 4, wherein the step of correcting the feedback coordinates corresponding to the exposure points, respectively, according to the exposure offset values corresponding to the exposure points, comprises:
determining which ones of the exposure points require to be currently corrected, to obtain a current correction object;
translating the current correction object to a preset position of the feedback coordinate system; and
returning to the step of determining which ones of the exposure points require to be currently corrected, until all of the exposure points have been corrected.

6. A method of improving exposure accuracy, comprising:
defining an exposure area on a substrate;
acquiring a plurality of exposure points from the exposure area, to obtain a set of the exposure points;
detecting a plurality of exposure offset values corresponding to the exposure points in the set of the exposure points, respectively, to obtain a set of the exposure offset values; and
correcting the exposure points corresponding to the exposure offset values, respectively, based on the set of the exposure offset values.

7. The method as claimed in claim 6, wherein the step of acquiring the plurality of exposure points from the exposure area, to obtain the set of the exposure points, comprises:
acquiring a plurality of exposure patterns from the exposure area;
acquiring corresponding exposure points of each of the exposure patterns, to obtain a plurality of subsets of the exposure points corresponding to each of the exposure patterns; and
determining the set of the exposure points based on the plurality of subsets of the exposure points.

8. The method as claimed in claim 7, wherein between the step of acquiring the plurality of exposure patterns from the exposure area and the step of acquiring corresponding exposure points of each of the exposure patterns, the method further comprises:
detecting a plurality of image definitions of the plurality of exposure patterns; and
acquiring corresponding exposure patterns whose the image definitions satisfy a preset condition, to obtain a plurality of exposure patterns to be extracted;
wherein the step of acquiring corresponding exposure points of each of the exposure patterns, to obtain the plurality of subsets of the exposure points corresponding to each of the exposure patterns, comprises: acquiring the exposure points of each of the exposure patterns to be extracted, to obtain the subsets of the exposure points corresponding to each of the exposure patterns to be extracted.

9. The method as claimed in claim 8, wherein the step of acquiring corresponding exposure patterns whose the image definitions satisfy the preset condition, to obtain the plurality of exposure patterns to be extracted, comprises:
determining corresponding exposure patterns to be currently processed, to obtain a current processing object;
determining whether the image definition of the current processing object satisfies the preset condition or not;
if the image definition of the current processing object satisfies the preset condition, determining that the current processing object is one of the exposure patterns to be extracted; and
returning to the step of determining corresponding exposure patterns to be currently processed, until all of the exposure patterns have been determined.

10. The method as claimed in claim 6, wherein the step of detecting the plurality of exposure offset values corresponding to the exposure points in the set of the exposure points, respectively, to obtain the set of the exposure offset values, comprises:
acquiring exposure values corresponding to the exposure points in the set of the exposure points, respectively;
calculating differences between the exposure values and preset reference values corresponding to the exposure points, respectively, to obtain the plurality of exposure offset values; and
constructing the set of the exposure offset values according to the plurality of exposure offset values.

11. The method as claimed in claim 6, wherein the step of correcting the exposure points corresponding to the exposure offset values, respectively, based on the set of the exposure offset values, comprises:
constructing a feedback coordinate system of the set of the exposure points based on the set of the exposure offset values;
marking a plurality of coordinates of the exposure points in the feedback coordinate system, respectively, to obtain a plurality of feedback coordinates corresponding to the exposure points; and
correcting the feedback coordinates corresponding to the exposure points, respectively, according to the exposure offset values corresponding to the exposure points.

12. The method as claimed in claim 11, wherein the step of correcting the feedback coordinates corresponding to the exposure points, respectively, according to the exposure offset values corresponding to the exposure points, comprises:
determining which ones of the exposure points require to be currently corrected, to obtain a current correction object;
translating the current correction object to a preset position of the feedback coordinate system; and
returning to the step of determining which ones of the exposure points require to be currently corrected, until all of the exposure points have been corrected.

13. A device of improving exposure accuracy, comprising:
an exposure unit configured to define an exposure area on a substrate;
an acquiring unit configured to acquire a plurality of exposure points from the exposure area, to obtain a set of the exposure points;
a detection unit configured to detect a plurality of exposure offset values corresponding to the exposure points in the set of the exposure points, respectively, to obtain a set of the exposure offset values; and
a correction unit configured to correct the exposure points corresponding to the exposure offset values, respectively.

14. The device as claimed in claim 13, wherein the acquiring unit is also configured to:
acquire a plurality of exposure patterns from the exposure area;
acquire corresponding exposure points of each of the exposure patterns, to obtain a plurality of subsets of the exposure points corresponding to each of the exposure patterns; and
determine the set of the exposure points based on the plurality of subsets of the exposure points.

15. The device as claimed in claim 13, wherein the detection unit is also configured to:
acquire exposure values corresponding to the exposure points in the set of the exposure points, respectively;
calculate differences between the exposure values and preset reference values corresponding to the exposure points, respectively, to obtain the plurality of exposure offset values; and
construct the set of the exposure offset values according to the plurality of exposure offset values.
